(19) United States
(12) Patent Application Publication
(10) Pub. No.: US 2024/0049498 A1
(43) Pub. Date: Feb. 8, 2024

(54) OLED WITH PASS-THROUGH HOLE

(71) Applicant: OLEDWorks GmbH, Aachen (DE)

(72) Inventors: Michael BOROSON, Pittsford, NY (US); Thomas HOEGEN, Niederzier (DE)

(21) Appl. No.: 18/340,523

(22) Filed: Jun. 23, 2023

Related U.S. Application Data
(63) Continuation of application No. 16/893,165, filed on Jun. 4, 2020, now abandoned.
Application No. 16/893,165 is a division of application No. 16/289,305, filed on Feb. 28, 2019, now abandoned.

(51) Int. Cl. H10K 50/84; H10K 50/805; H10K 50/844; H10K 71/00

(52) U.S. Cl. CPC H10K 50/84; H10K 50/805; H10K 50/844; H10K 71/00

(57) ABSTRACT

A fully encapsulated OLED panel with a first area for light emission which entirely surrounds a non-light emitting second area with a pass-through hole with cut edges comprising: a substrate that extends throughout the first area and second areas to the cut edges of the pass-through hole; a first electrode over the substrate located at least in the first area; at least one organic layer for light emission located over the first electrode in the first area but is not present in the second area; a second electrode located over the at least one organic layer in at least in the first area; encapsulation at least located over the second electrode in first area, over the second area and extends at least partially into the cut-edges of the pass-through hole; and wherein the area of the pass-through hole is smaller than the second area so that the second area entirely surrounds the pass-through hole. Arranging a smaller pass-through hole within a larger non-light emitting area enables encapsulation within the pass-through hole.

### CROSS-REFERENCE TO RELATED APPLICATION

This application is a divisional of prior application Ser. No. 16/289,305 filed Feb. 28, 2019, entitled “OLED WITH PASS-THROUGH HOLE”; the disclosures of which are incorporated by reference herein. Reference is made to commonly assigned U.S. application Ser. No. 16/144,139, filed Sep. 27, 2018, titled “Method for Making OLED with Pass-Through Hole”.

### BACKGROUND

OLED panels, which rely on OLED technology to generate light, offer many advantages for general lighting and display purposes. They are efficient in terms of light output for power consumed. They are low voltage which helps avoid potential electrical shocks, less prone to sparking in potentially explosive environments, and they reduce loads in the supporting electrical system. The spectrum of emitted light can be varied using appropriate internal designs. They produce little or no UV or IR light. They are instant on; that is, they emit light immediately whenever electrical power is supplied. OLED light sources are inherently flat area light sources. They offer several advantages over LED panels. They can be made even thinner (for example, less than 1 mm thick) and they produce less heat under normal operating conditions. However, OLED lifetimes can be an issue. Both LED and OLED panels can be made on flexible or curved substrates even though OLED is preferred for these types of applications. In summary, OLED panels can be useful for lighting and display applications. They are efficient, low voltage, cool to the touch, and are thin. Luminaires (a complete unit with a light source (i.e. a lamp) and a supporting part (i.e. a lamp-holder) that provides light and illumination) can be designed to utilize OLED panels as the light sources. Displays using OLED panels can either be direct, for example, the OLED panel contains individually controlled Red, Green and Blue (RGB) subpixels; Red, Green, Blue and White (RGBW) subpixels; individually controlled White subpixels with a color filter array or individually controlled Blue subpixels with a color conversion array; or indirect, for example, the OLED panel is used as a white backlight for an LCD panel used for RGB display.

In the lighting industry, luminaire design is often of critical importance. Besides addressing general or specific illumination needs, luminaires become part of the architectural environment. It would be very desirable to design luminaires that take advantage of some of the unique physical characteristics of OLEDs that differ from other light sources such as LED. The same considerations can also be applied to display applications.

Generally speaking, an OLED panel for use in a luminaire or a display would have at least three parts: an OLED substrate or support, an OLED light-emitting unit, and electrical connections which provide power to the internal OLED electrodes from an external source. An OLED light-emitting unit would have at least one organic electroluminescent layer between two electrodes on a substrate and would be encapsulated to protect the electroluminescent layer(s) from air and/or water. Typically, the OLED panel would have a central emissive area (continuous for lighting applications or subpixels for direct display applications) surrounded by non-emitting borders. Electrode contact pads, which are connected to the internal electrodes, are often located in these non-emitting border areas on the same face of the substrate as the electroluminescent layers.

For some luminaire designs, it would be desirable to use an OLED panel as a light source where the OLED panel has a pass-through hole. In such cases, the OLED lighting panel would have at least one hole or opening that is large enough to allow objects behind the panel to be viewed through the hole. Alternatively, the pass-through hole is large enough so that a solid element can pass through the hole. In both cases, the pass-through hole does not affect light emission in most of the surrounding area of the panel. The pass-through hole would be entirely within the central emission area of the OLED panel and is surrounded on all sides by a continuous and uninterrupted emitting area of the OLED panel. The space within the border of the pass-through hole is entirely empty; that is, there is no part of the OLED panel that exists within the hole. It is not merely a transparent and non-emitting area within the central emission area of the OLED panel. A pass-through hole could also be referred to as a through-hole, thru-hole or clearance hole, all of which are equivalent terms.

The OLED panel with a pass-through hole could also be a pixelated image display. In this case, the pass-through hole would be within the central display area of the OLED and is surrounded on all sides by a continuous and uninterrupted display area of the OLED panel. In such cases, the OLED display panel would have at least one hole or opening that is large enough to allow objects behind the panel to be viewed through the hole. Alternatively, the pass-through hole is large enough so that a solid element can pass through the hole.

In some designs, the pass-through hole is large enough that objects behind the panel are clearly visible. It is often not necessary that an entire object must be viewed, but only that it is sufficiently viewed to be detectable. However, the exact size of the pass-through hole needed to allow visibility of objects depends on many factors.

Firstly, since the light from the object (whose intensity is inversely proportional to the distance from the object) must pass through the hole, it is clear that the hole must be large enough to allow a sufficient amount of light from the object to pass to be viewable. This situation is complicated by the surface of the OLED panel which also emits light towards the viewer, thus partially diluting the light coming from the object. For this reason, it would be highly desirable that the pass-through hole to be entirely surrounded by a non-light emitting area. Not only does this improve the optics involved, but surrounding the pass-through hole with a non-emitting area highlights the presence of the hole and provides an aesthetic appeal.

Secondly, there is a problem related to the parallax effect when viewing through a hole. For example, consider the schematic diagram in FIG. 1A where P is the viewer, O is the optical axis of viewing, s is the distance between the hole and the viewer, f is the distance between the hole and the object, d is the total distance between the viewer and object, H is the size of the hole opening and q_{d} represents the viewable size of the object that lies in plane S.

FIG. 1B illustrates the problem of viewing objects through a hole opening H which is very small, such as a pinhole. Assuming that the viewer P is as least the same distance in front of the hole as the distance of an object from the back of the hole, solid sightlines a, coming from the edge of an object, will not be in the field of view to the viewer P. Dotted sightlines b, also coming from the edge of the object but would be in the view of field to the viewer P, are blocked. Dashed sightlines c, coming from the viewer P through the hole opening H, will only subtend a limited part q_{d} of the object. In this case, this subtended viewing area may not be enough to visibly detect the object through opening H.

FIG. 1C illustrates a similar situation where the hole opening H is large; in this example, at least as big as the object to be viewed through the hole. Assuming again that the viewer P is as least the same distance in front of the hole as the distance of an object from the back of the hole, solid sightlines a, coming from the edge of an object, will no longer exhibit any parallax issues. Dotted sightlines b, also coming from the edge of the object will be in the field of view to the viewer P. Sightlines c, coming from the viewer P through the hole opening H, will subtend over an area greater than the object. In this case, the object should be viewable through opening H.

Typically, for OLED panels used as lighting, the distance s between the viewer and panel would generally in the range of multiple meters and the distance f between the object and the back of the panel would be typically be the same or less than the distance s and often significantly less. In such situations, it is easy to see that the size H of the pass-through hole would need to be relatively large in order to have a significant viewing size of the object. Even in the case where the OLED panel is a display and the position of the viewer is much closer (typically 0.1-0.5 meter) to the hole, the size of the hole would still need to be much larger than the pixels in order for an object to be visible. The depth or thickness of the hole can impact the hole size needed for visibility of objects; however, OLED panels and housings are generally thin enough not be a significant consideration in this regard.

In some designs, there can be a solid element that extends through the pass-through hole or at least partially within the pass-through hole. In such cases, the OLED panel with the pass-through and the solid element together form a single integral unit. In some designs, the presence of the solid element is strictly decorative and the OLED panel/solid element unit provides architectural interest. In other designs, the solid element provides a function such as mechanical support or space to conceal electrical wires.

U.S. Pat. No. 8,053,977 describes OLEDs for phototherapy with perforations that allow fluids and/or heat to escape when onto human skin. The holes appear to be small (a diameter of 40 μm is given as an example) relative to the overall size of the OLED. This reference also describes a method where (presumably via masking) the bottom electrode is not deposited near the perforation area, the organic layers are deposited over the bottom electrode and in part, the substrate but not within the perforation area, with a top electrode deposited over the organic layers and substrate in the perforation area followed by encapsulation over everything. A hole is then formed within the perforation area. However, this method allows light to be generated in the organic layers between the side edge of the bottom electrode and the top electrode on the substrate near the perforation. In this case, not only will light be emitting from the surface up to the edge of the perforation but also through the side walls of the perforation. While this isn't typically a problem for a pinhole, light generated from the side walls within a larger hole can be undesirable from an aesthetic viewpoint. Moreover, the encapsulation for the side edge of the organic layers is provided only by the top electrode in this method. While electrodes are typically composed of inorganic materials (i.e. metal or transparent metal oxides) which do not transport water or air, they are also thin and are prone to formations of tiny cracks and fissures. Encapsulation by an electrode alone may not provide sufficient environmental protection.

CN104576709 describes a wearable OLED display (i.e. wristwatch) where the pixels have ventilation holes in order to make it breathable. The holes are small (80 microns). This reference describes the formation of an OLED (anode/organic/cathodes/SiN protective layer) uniformly over a flexible base, forms the holes, then encapsulates. The holes are cone shaped with sloping sides (small at the front of the substrate then larger towards the back). Presumably, the sloping sides allow for encapsulation over the end of the organic layer as opposed to having vertical edges where it would be difficult to cover the edge of the organic layer. However, the size of the emitting area is then determined by the size of the cathode (the topmost layer), which is the smallest area. This decreases the amount of overall light emission.

WO2018/032863 also describes a wearable OLED wristwatch with ventilation holes that are very small. This reference teaches the use of a package film to line the sides of the ventilation hole to prevent moisture and air penetration into the organic layers prior to filling the holes with hydrophobic gas-permeable polymeric material. This reference describes the formation of an encapsulated OLED (anode/organic/cathode/protective layer) uniformly over a flexible base, forms the holes, then re-encapsulates the side walls of the pass-through hole with a protective film.

In all of the above references, the holes in the OLED are very small and are sized to allow for the pass-through of air and fluid when the OLED is placed next to the skin. The holes as described would not large enough to view the skin through the OLED.

It is the object of the invention to provide an OLED with a pass-through hole by arranging the internal structure of the OLED so that when the pass-through hole is formed in the fully encapsulated OLED, the encapsulation remains unbroken. In particular, the cut edges of the pass-through hole remain encapsulated and no further treatment or re-encapsulation is needed. Without previous arrangement of the internal structures of the OLED before encapsulation, the edges of the moisture-and oxygen-sensitive OLED layers may become exposed to the atmosphere along the side walls of the pass-through hole when the pass-through hole is formed in the emissive area of an OLED. It is well known that moisture and oxygen can travel laterally through thin organic layers if the edge of the layer is left exposed. For cost and availability considerations, it would be advantageous to begin with an existing fully encapsulated OLED and then form the pass-through hole. By appropriate arrangement of the internal OLED structures, it would not be necessary to re-establish the encapsulation along the newly formed cut edges along the side walls of the pass-through hole of the OLED panel in order to maintain its useful lifetime. Moreover, by arranging the sensitive internal layers of the OLED to avoid the region in which the pass-hole will be created, damage to the internal layers during pass-through hole formation is greatly reduced. An OLED panel with a pass-through hole that allows visibility through the opening is useful because it enables unique designs of luminaires or displays. Moreover, a large pass-through hole which allows solid objects to pass through the hole provides unique design opportunities.

### SUMMARY

Disclosed is a fully encapsulated OLED panel with a first area for light emission which entirely surrounds a non-light emitting second area with a pass-through hole with cut edges comprising: a substrate that extends throughout the first area and second areas to the cut edges of the pass-through hole; a first electrode over the substrate located at least in the first area; at least one organic layer for light emission located over the first electrode in the first area but is not present in the second area; a second electrode located over the at least one organic layer in at least in the first area; encapsulation at least located over the second electrode in first area, over the second area and extends at least partially into the cut-edges of the pass-through hole; and wherein the area of the pass-through hole is smaller than the second area so that the second area entirely surrounds the pass-through hole.

At least part of the encapsulation along the cut-edges of the pass-through hole can be provided by an insulating layer, desirably glass frit or aluminum oxide.

The first electrode might or might not be in the second area. The encapsulation over the first and second areas can extend along the cut-edges of the pass-through hole so that it is in direct contact with the substrate in the second area.

The first electrode may extend throughout the first and second areas to the cut edges of the pass-through hole. The encapsulation over the first and second areas also extends along the cut-edges of the pass-through hole so that it is in direct contact with at least part of the first electrode in the second area. In some embodiments, part of the first electrode in the second area is not covered by encapsulation so that it can form an accessible electrode contact pad within the emission area.

The minimum width of the second area running from the edge of the pass-through hole to the edge of the first area is at least 3 mm in all directions.

The OLED panel is desirably an OLED lighting panel for illumination or incorporation into a luminaire. If the OLED lighting panel has an emission surface of 10,000 mm² or less, the pass-through hole has a minimum opening area of at least 1.7 mm². If the OLED panel has an emission area of greater than 10,000 mm², the pass-through hole has a minimum opening area of at least 0.017% of the total emission surface.

Such OLED panels may be made by ablation or shadow masking processes.

It is the object of the invention to provide an OLED panel with a pass-through hole large enough so objects can be viewed through the hole or that solid objects can extend through the hole. In order to form an OLED panel with a pass-through hole, the OLED organic layers, which are sensitive to water and oxygen, along with the electrodes are arranged prior to hole formation so that the pass-through hole does not pass directly through them. In particular, the structure of the OLED panel is arranged so that there is a non-emitting area of encapsulating material through which a smaller pass-through hole is created. This provides encapsulation of the side edges of the internal OLED layers as well as a non-emitting border surrounding the pass-through hole on the emission side. An OLED panel with a pass-through hole that allows visibility through the opening is useful because it enables unique designs of luminaires or displays.

### BRIEF DESCRIPTION OF THE DRAWINGS

FIGS. 1A-1C are schematic illustrations of the relationship of the size of a hole opening to the visibility of objects behind the hole.

FIG. 2 is an overhead view of an OLED panel 100 arranged to have a non-light emitting area surrounded by a light-emitting area.

FIG. 3 is an overhead view of an OLED panel 200 with a pass-through hole through the non-light emitting area.

FIG. 4A is a cross-sectional view of OLED panel 100. FIG. 4B is a cross-sectional view of OLED panel 200.

FIGS. 5A-5D are cross-sectional views that show some of the steps of making OLED panel 210 using laser ablation.

FIGS. 6A-6E are cross-sectional views that show some of the steps of making OLED panel 220 using an insulating layer and laser ablation.

FIG. 7 shows an example of a thermal deposition process using a shadow mask with shadow mask connectors that do not interfere with the deposition.

FIGS. 8A-8C are cross-sectional views that show some of the steps in making OLED panel 100 using a shadow mask held in position by magnetism.

FIGS. 9A-9E are cross-sectional views that show some of the steps in making OLED panel 230 where the first electrode in present in the non-emitting area around the pass-through hole.

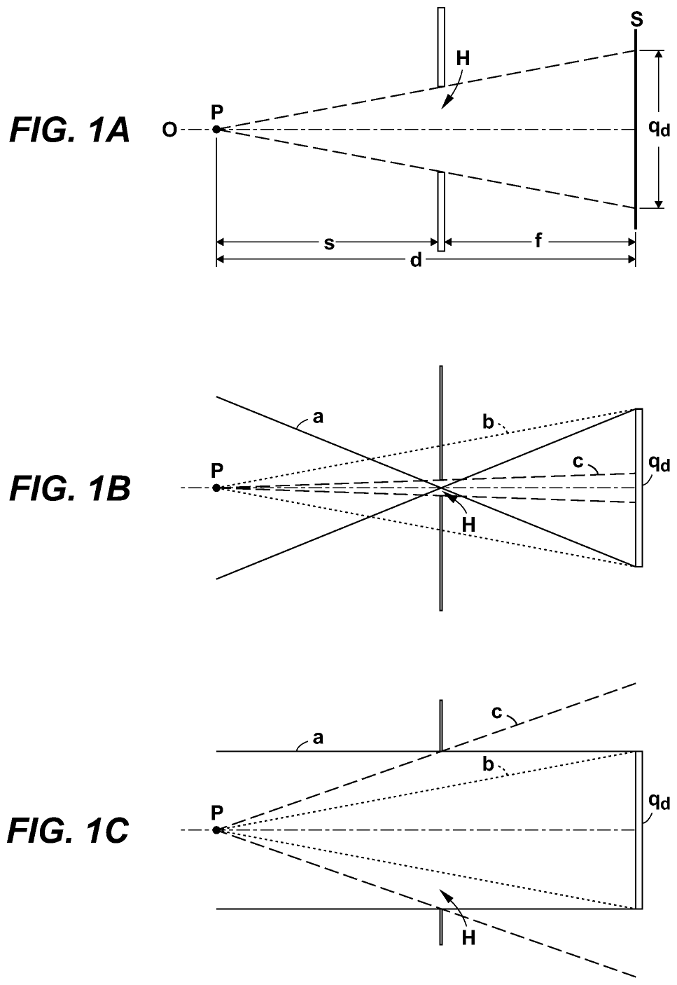

Because some of the structures involved are very small, the Figures are illustrative only and are not drawn to scale.

### DETAILED DESCRIPTION

In the following, the example OLED panels are all shown as being rectangular in shape. However, the OLED panels are not limited to any particular shape and so, may be square, circular, oval, triangular or an irregular shape. Rectangular, square or circular panels are preferred. In addition, although the examples refer to using an OLED as a specific example of a light-emitting unit, any kind of light-emitting unit containing organic material would be generally useful. The OLED panels are flat and thin. By “flat”, it is meant that the thickness dimension is much less (generally less than 1:100) than the length and/or width dimensions. Note that “flat” refers only to the ratio of thickness to the other two dimensions; thus a “flat” OLED can have a bent or curved shape. Moreover, an OLED panel will have top and bottom “faces” along the length and width dimensions. At least one of these faces will be light emissive. An “edge” of the OLED panel (or of any of its internal layers) is along the thickness dimension. A “pass-through” hole has an unobstructed opening that an appropriately sized solid object or element can freely pass through the opening from one side of the hole to the opposite side and is large enough that objects can be viewed through the hole.

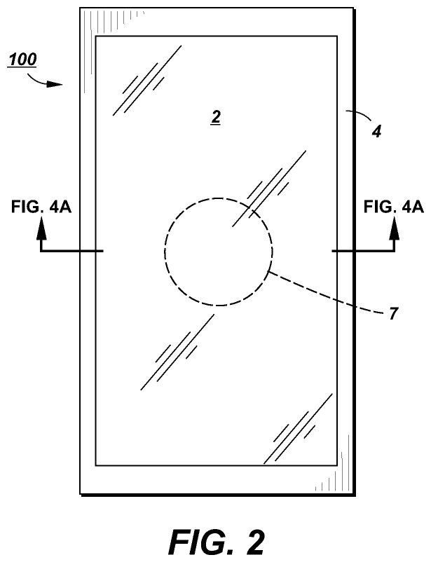

FIG. 2 is an overhead view of an OLED panel 100 without a pass-through hole but whose internal structure in non-emitting area 7 has been arranged to allow the creation of a pass-through hole within non-emitting area 7. Non-light emitting area 7 is entirely surrounded by the light-emitting area 2 of the OLED panel. There is also a non-light emitting area 4 that surrounds the outside of the light-emitting area 2. All or part of outside area 4 typically lies outside the encapsulation and provides a location for contact pads for supplying external electrical power.

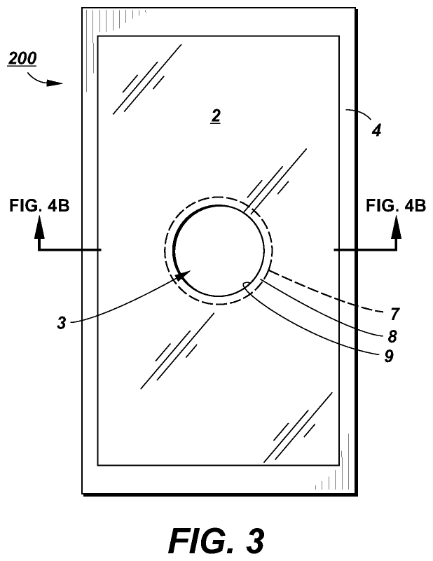

FIG. 3 is an overhead of an inventive OLED panel 200 where a pass-through hole 3 has been formed entirely within the non-light emitting area 7. The pass-through hole 3 has cut-edges 9. The pass-through hole 3 is smaller in area than the non-emitting area 7 and located to leave a non-light-emitting border 8 that entirely surrounds the pass-through hole 3 on all sides and in all dimensions. The pass-through hole 3 runs completely through the entire OLED panel 200. The light-emitting area 2 that completely surrounds the non-emitting border 8 represents a first area for light emission while the non-light-emitting border 8 that entirely surrounds the pass-through hole 3 represents a second non-light emitting area within the OLED panel.

Although the pass-through hole shown in FIG. 3 is circular, the pass-through hole may be any desired shape. For example, it could be oval, square, rectangular, a regular polygon (such as a star or an octagon) or an irregular shape. A circle or square is preferred. The walls or sides of the pass-through hole are desirably vertical (that is, perpendicular to the front and back surfaces of the OLED panel) but may be slanted either front-to-back or back-to-front if desired. The side walls need not be straight, but can be curved or stepped if desired.

It is desirable that the non-emitting border surrounding each pass-through hole has the same shape and outline as the pass-through hole (for example, as shown in FIG. 3) although it is not necessary. It is also desirable that the non-emitting border area extend from the outside cut-edge of the pass-through hole in all directions uniformly for the same distance (for example, as shown in FIG. 3). However, in all cases, the non-light emitting border must entirely surround the pass-through hole so that the light-emitting area never extends to the cut edge. That is, the non-light emitting border must always lie between and separates the cut edge of the pass-through hole from the light-emitting area.

The size or area of the opening of the pass-through hole is important in order to enable viewing of objects through the pass-through hole or to allow solid elements to fit within the pass-through hole. Small holes such as pinholes (generally considered to be less than 1 mm in diameter or about 0.8 mm² in area) do not have a large enough opening to allow a sufficient amount of light to pass through in order to make an object visible (without aid) through the OLED panel nor a large enough viewing angle of the object at typical viewing and object distances. It would also very difficult to fit a solid element within a pinhole since the solid element would have to be very thin and so, would not be rugged and would be vulnerable to breakage, would not have any internal space for providing any additional function and would be difficult to introduce into the pass-through hole.

The useful area of the pass-through hole will somewhat depend on the size of the OLED panel because the viewing distance will typically vary according to the overall size of the OLED panel. In general, the viewing distance will be shorter for smaller OLED panels and will be longer for larger OLED panels. For this reason, the pass-through hole for small OLED panels, defined as having an emission surface of 10,000 mm² (100 cm²) or less, should have a minimum opening area of at least 1.7 mm² (roughly equivalent to a circle of 1.5 mm diameter), more desirably at least 7 mm² (roughly equivalent to a circle of 3 mm diameter), even more desirably at least 20 mm² (roughly equivalent to a circle of 5 mm diameter) and most desirably at least 80 mm² (roughly equivalent to a circle of 10 mm diameter).

For larger OLED panels, defined as those with an emission area of greater than 10,000 mm² (100 cm²), the pass-through hole should have a minimum opening area of at least 0.017% of the total emission surface (including the pass-through hole). This would roughly correspond to a circular pass-through hole of diameter 0.15 cm or 1.5 mm (area=0.017 cm²) for a rectangular OLED panel with an emission surface of 100 cm² (5 cm×20 cm). More desirably, the pass-through hole should have an opening area of at least 0.07% of the total emission surface. This would roughly correspond to a circular pass-through hole of diameter 0.3 cm or 3 mm (area=0.07 cm²) for the same 5 cm×20 cm OLED panel. Even more desirably, the pass-through hole should have an opening area of at least 0.2% of the total emission surface. This would roughly correspond to a pass-through hole of diameter 0.5 cm (area=0.2 cm²) for a 5 cm×20 cm OLED panel. Most desirable, the pass-through hole should have an opening area of at least 0.8% of the total emission surface. This would roughly correspond to a circular pass-through hole of diameter 1.0 cm (area=0.8 cm²) for a 5 cm×20 cm OLED panel. Generally speaking, it is desirable for OLED lighting panels, used for illumination purposes, should have an emissive area of at least 100 cm².

In the context of this invention, the area of the pass-through hole refers to the area of the unobstructed part of the pass-through hole that is created when an opening is formed in an OLED panel. The terms “cut edges” and “side walls” refer to the newly created surfaces in the thickness direction (perpendicular to the flat planes, and parallel to the emissive direction, of the OLED panel) when an opening is formed in the OLED panel and may be used interchangeably.

Although FIG. 3 illustrates an example of an OLED panel with just one pass-through hole with a non-emitting border, an OLED panel may contain more than one pass-through hole and border if desired. The pass-through holes and associated borders may be arranged in a pattern or may be located randomly across the emission surface. The pass-through holes and associated borders may all be the same size or different sizes. The pass-through holes and associated borders may be all the same shape or may be a mixture of different shapes. Moreover, there can be more than one pass-through hole located within a single non-emitting area.

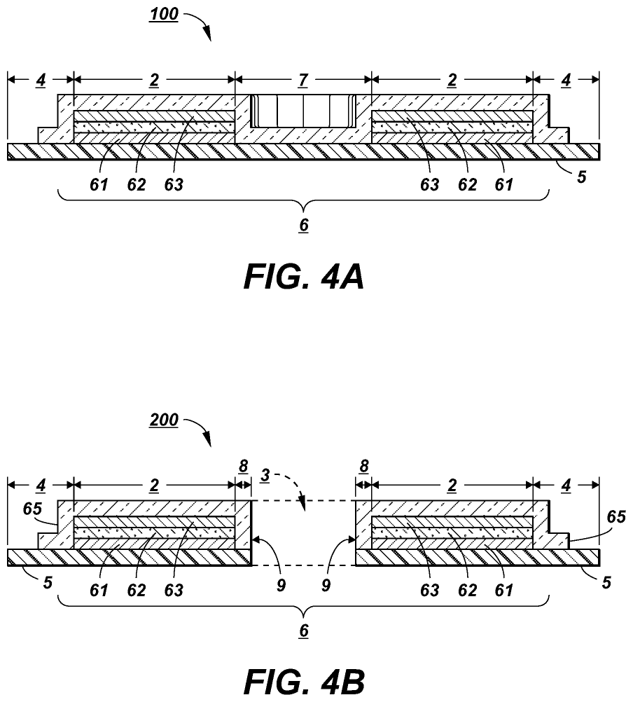

FIG. 4A shows a cross-section of a first embodiment according to OLED panel 100 (FIG. 2) where the internal structure of the OLED has been arranged to allow formation of a pass-through hole without disturbing the encapsulation of sensitive OLED layers but where the pass-through hole has not been created yet. There is an OLED substrate 5 on which a first electrode 61 is patterned as to not be present in non-light emitting area 7. Over the first electrode, there is at least one organic layer 62 for light emission. The organic layer(s) 62 is arranged to correspond to the first electrode 61 so that it is not present in non-light emitting area 7 either. Over the light emitting layer(s) 62 is a second electrode 63 which is also arranged so it is not in the non-emitting area 7. Together, the first electrode 61, the organic layer(s) 62 and the second electrode 63 comprise a light-emitting OLED so that light is emitted in area 2 as indicated. Over the OLED light-emitting unit (61, 62, and 63) in area 2 as well as the OLED substrate 5 in area 7 and at least part of the non-light emitting area 4, there is encapsulation layer 65 which is in contact with the OLED substrate 5 in the non-light emitting region 7. The encapsulation layer 65, along with internal layers 61, 62, and 63 forms a complete OLED unit 6 (which is on OLED substrate 5) in light-emitting region 7. Since none of these internal layers, all of which are necessary for light emission, are present in region 7, there is no light emission in that area. Not shown in this view are electrical contact leads that will pass through the encapsulation for connection of the first and second electrodes to an external power source.

FIG. 4B shows a cross-section of the first embodiment according to OLED panel 200 (FIG. 3) where a pass-through hole 3, with cut-edges 9, has been created within the non-light emitting area 7. The formation of the pass-through hole 3, being smaller than the non-emitting area 7, will create a non-light emitting border 8 that lies along the vertical cut edges of the pass-through hole 3. In this way, the side edges of the organic layer(s) 62 are left covered by the encapsulation layer 65 during and after the pass-through hole 3 is created. Because the internal OLED layers are set back away from the cut edges of the pass-through hole, the chance of shorting via incidental contact between the first and second electrodes caused by mechanical disruption during the cutting process are reduced.

It should be noted that the substrate 5 extends from the outside edge of area 4, through the first light-emitting area 2 and the non-light-emitting border 8 to the side wall of the pass-through hole 3. In other words, the hole in the substrate 5 has the same area as the pass-through-hole 3 and the substrate 5 directly borders the cut edge 9. The edges of the internal OLED layers (61, 62 and 63) are set back from the cut edge 9 of the pass-through hole 3 and are separated from the cut edge 9 of the pass-through hole 3 by the impermeable material (encapsulation 65) that occupies the non-light emitting border 8 so that all layers, including the encapsulation 65, still overlie the substrate 5. This is important because if the substrate did not extend fully to the cut-edge of the pass-through hole (and across the entire non-light emitting area 7 before the pass-through hole is created as FIG. 4A), it would be very difficult to maintain and support the encapsulation material 65 in position along the side walls of the pass-through hole. The presence of the substrate in this area is necessary to provide support to the encapsulation before and during the creation of the pass-through hole.

In this first embodiment, the side edges of the first electrode 61, the organic layer(s) 62 and the second electrode 63 are all vertically aligned. Thus, light emission in the light emitting region 2 primarily occurs at some angle to the OLED substrate and very little, if any, light is emitted parallel to the OLED substrate into the laterally adjacent non-light emitting border 8. It is very desirable to have at least 80% of the light emission from light-emitting area 2 to be emitted at an angle of at least 10 degrees but not more than 170 degrees from the plane of the OLED substrate. This will minimize any light emission through the encapsulation layer 65 in border 8 into the pass-through hole 3.

There are a number of methods that can be used to arrange internal layers 61, 62 and 63 of OLED unit 6 to form a non-light emitting area that is entirely surrounded by a light-emitting region. Generally, the methods for making an OLED device with a pass-through hole where the pass-through hole is located within a non-emitting area will involve the steps of
forming a first electrode in at least a first area of a substrate that has first and second areas;
forming at least one organic layer for light emission over the first electrode only in the first area;
forming a second electrode over at least the organic layer(s) in the first area;
forming encapsulation over at least the first and second areas;
forming a pass-through hole with cut-edges through the second area, where the area of the pass-through hole is smaller than the second area so that the second area entirely surrounds the pass-through hole.

One suitable method for forming the internal OLED layers in the desired areas can be where the layer is patterned by removal of the layer(s) in the desired area. Alternatively, masking methods may be used so that the layer(s) are not deposited in the desired area.

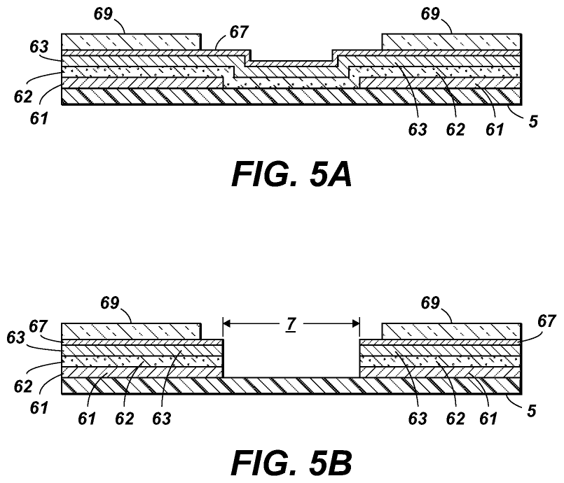

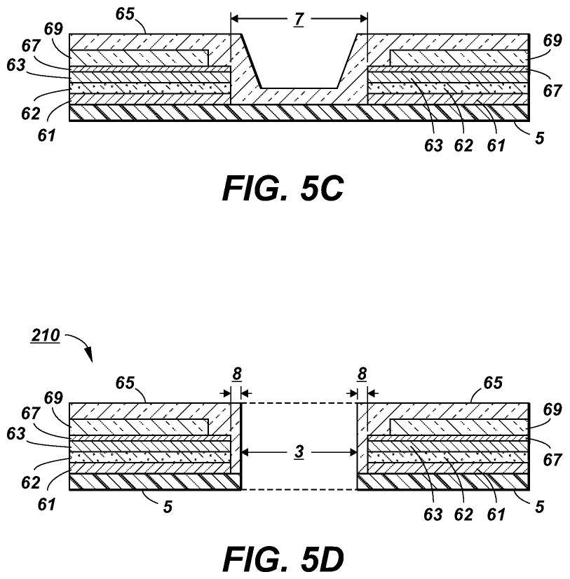

One suitable method to make an OLED panel 210 (similar to 200 as shown in FIG. 3) involving removal of internal layers by laser ablation is shown in FIGS. 5A-5C. In a first series of steps, FIG. 5A shows where the first electrode 61 has been patterned to cover the entire surface of OLED substrate 5 except in non-light emitting area 7, followed by uniform deposition of the organic layer(s) 62, second electrode 63 and a protective layer 67. In this embodiment, the protective layer 67 is silicon nitride. Then a patterned layer of an optically clear polymer film 69 is formed so there is an opening that includes the area 7. Suitable polymer films are well known (such as those sold by Rolic (Switzerland)) and can be patterned by printing and UV curing.

As shown in FIG. 5B, all of the layers in non-light emitting area 7 are then removed down to the OLED substrate 5 within the opening in the polymer film 69. The area removed is less than and entirely surrounded by the area of the opening in the polymer film. The removal of these layers can be by the use of an IRR femtosecond laser.

As shown in FIG. 5C, the entire surface is then encapsulated. In this embodiment, the encapsulation 65 is by lamination with a barrier film. Suitable barrier films serve as a water and air barrier. For example, one typical barrier film would be metallized PET. The barrier film can be attached to the surface using a suitable barrier adhesive (not shown).

Finally, as shown in FIG. 5D, OLED panel 210 with a pass-through hole 3 within non-light emitting area 7 is created where part of the encapsulation 65 is left to encapsulate the side edges of the pass-through hole 3 to form non-light emitting border 8. Creating a smaller pass-through hole within an area lacking the internal OLED layers so that the pass-through hole does not have to be created directly through the internal OLED layers reduces the chances of disruption of those layers and does not require later re-encapsulation. Samples of OLED panels with a pass-through hole prepared by this method did not show any degradation due to air and water penetration over a period of several months.

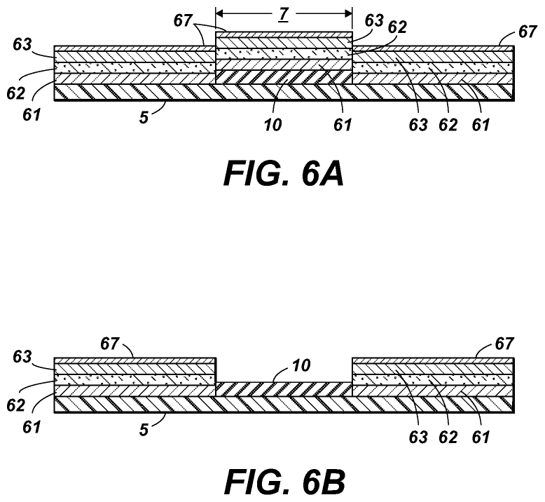

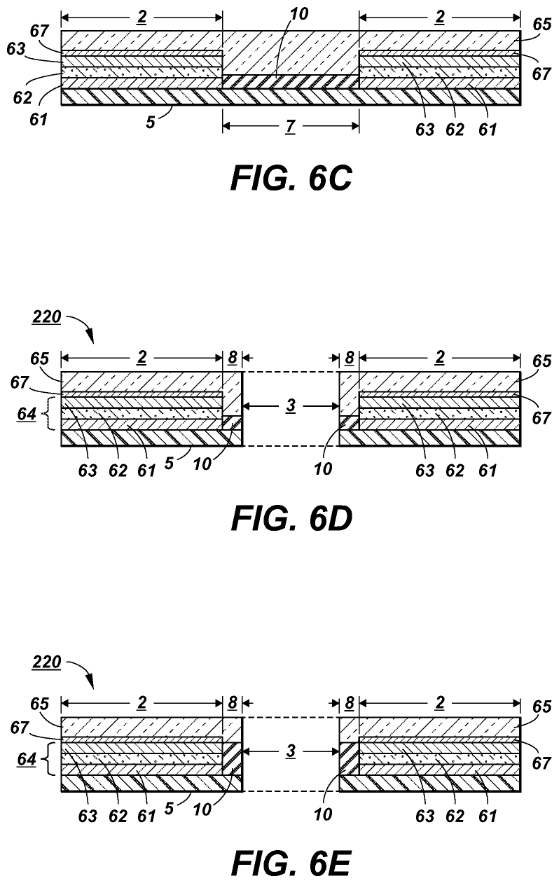

Another embodiment to make an OLED panel 220 (similar to 200 as shown in FIG. 3) involving laser ablation is shown in FIGS. 6A-6C. In this embodiment, an impervious insulating layer 10 is patterned to fill what will become non-light emitting area 7 over the substrate 5. Examples of suitable insulating layers would be glass frit, which can be screen printed and then fused to form an impervious moisture barrier or an inorganic oxide or nitride such as SiO₂, Al2O₃ or SiN. Over the entire surface (except for outside area 4) are deposited first electrode 61, organic layer(s) 62, second electrode 63, and optional protective layer 67.

Next, as shown in FIG. 6B, those portions of 61, 62, 63 and 64 overlying the insulating layer 10 in what will become non-light emitting area 7 are removed by laser ablation. This is possible since the insulation layer 10 is thermally stable and unaffected by the ablation process. Next, as shown in FIG. 6C, an encapsulation layer 65 is then deposited over the surface to create an OLED with an emitting area 2 as well as the non-light emitting area 7. Finally, as shown in FIG. 6D, OLED panel 220 is formed when a pass-through hole 3 is created through non-light emitting area 7 leaving a non-light emitting border 8 where the internal OLED layers along the cut edge are encapsulated by the encapsulation layer 65 and the remaining portion of the insulating layer 10.

In the illustrative embodiment of FIGS. 6A-6D, the height of the insulating layer 10 was smaller than the OLED stack 64 (layers 61, 62 and 63), However, the height of the insulating layer 10 may be chosen to be the same as or greater than the height of the OLED stack. This is illustrated in FIG. 6E. In such instances, the encapsulation of the internal layers along the side walls will be entirely the insulating layer 10.

Other methods to make an OLED panels similar to 200 as shown in FIG. 3 can involve shadow masking. However, typical shadow masking processes and techniques are generally not suitable for making the inventive OLED devices because the mask itself must be held close to the surface in order to prevent deposition. However, the part (non-light emitting area 7) of the inventive OLED devices where deposition should be prevented is entirely surrounded by the light-emitting area 2 of the OLED where deposition is required. However, the mask requires supports to hold the mask in the desired position but yet the supports, if too close to the deposition surface, could prevent uniform material deposition and create uneven emission.

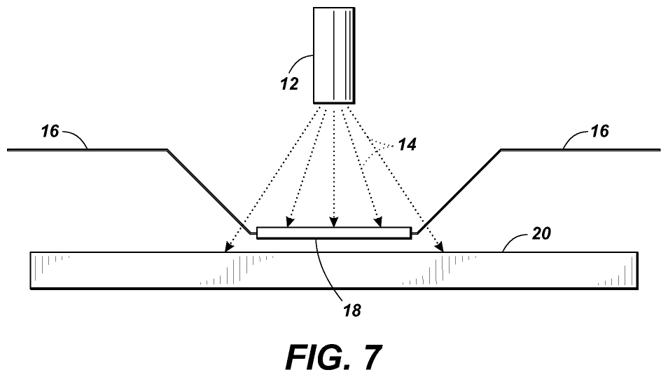

One solution to this problem is schematically shown in FIG. 7. There is a thermal evaporation source 12 which creates a vapor plume 14 of material to be coated. The plume 14 is generally cone shaped. The source 12 is generally located at some distance from the surface of the deposition substrate 20 in order to provide even deposition. The shadow mask 18, which must be located close to the deposition surface, is supported by shadow mask connectors 16 which are located up and away from the shadow mask. Desirably, the height, size and cross-section of the shadow mask connectors 16 should be selected such that no location within the shadow of the connectors 16 on the deposition surface 20 in the emitting area is less than 95% of the thickness of the material deposited in the non-shadowed areas, preferably no less than 99%. Alternatively, the height, size and cross-section of the connectors 16 should be selected such that the thickness uniformity of the emitting area is greater than 97.5% (1−(Max−Min)/(Max+Min)), preferably greater than 99.5%. Because the supporting connectors can be made narrow in cross-section and located relatively far from the deposition surface, the vapor plume 14 can pass around the connectors 16 without interference to allow even deposition.

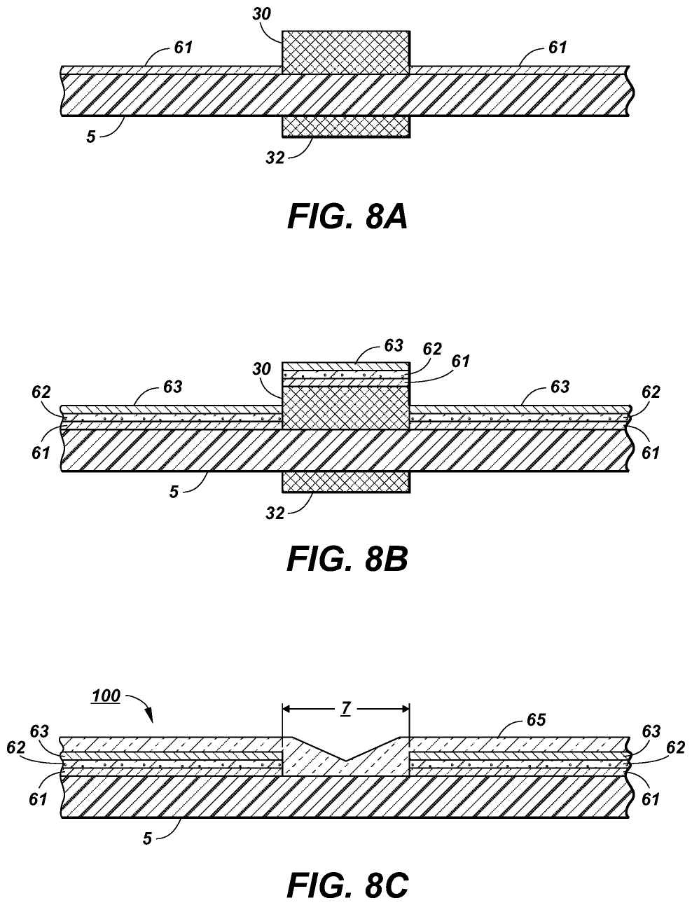

Another solution to this problem is the use of shadow masks that are held in place via magnetism; for example, as disclosed in U.S. Pat. No. 8,916,032. An example is shown in FIGS. 8A-8C.

In FIG. 8A, a magnetic mask 30 is held in contact with the substrate 5 by a magnetic mask holder 32 located on the backside of the substrate 5. In this embodiment, the magnetic mask 30 is located within and surrounded by a pre-patterned layer of first electrode 61. Then, as shown in FIG. 8B, organic layer(s) 62 and second electrode 63 are uniformly deposited over the first electrode 61 as well as the upper surface of the magnetic mask 30. Removal of the magnetic mask holder 32 from the bottom side of the substrate 5 releases the magnetic mask 30 along with any overlying layers in area 7 and followed by deposition of the encapsulation 65 over the surface, including the area previously occupied and protected by the magnetic mask 30 (as shown in FIG. 8C) results in the same OLED device 100 as shown in FIG. 4A. A pass-through hole 3 can then be created within the non-light emitting area 7 to make the same OLED device 200 as shown in FIG. 4B.

It is highly desirable that OLED lighting panels to have as uniform light emission is possible, although it is less important for OLED displays. However, in large OLED panels, the light emission may not be as uniform as desired since the electrodes can only be powered from the outside edges of the device and the voltage falls as the distance from the power source increases. This problem can sometimes be addressed by the use of more conductive auxiliary electrodes within the emitting area. However, this adds to the complexity of the device. However, it is possible to use the non-emitting area adjacent to the pass-through hole (which is located within and entirely surrounded by the emitting area) to form external electrode contacts adjacent to the pass-through hole. More uniform emission can be obtained by being able to supply power within as well as along the outside edge of the light-emission area.

While the outside edges of the OLED organic layer(s) need encapsulation to prevent moisture and air from penetration and lateral transport through the layer, this is not necessarily required for the first and second electrodes, assuming they are totally inorganic and made of metal or metal compounds such as metal oxides like ITO. The first and/or second electrodes can be arranged to extend through the encapsulation without exposure of the organic layer(s) to the atmosphere.

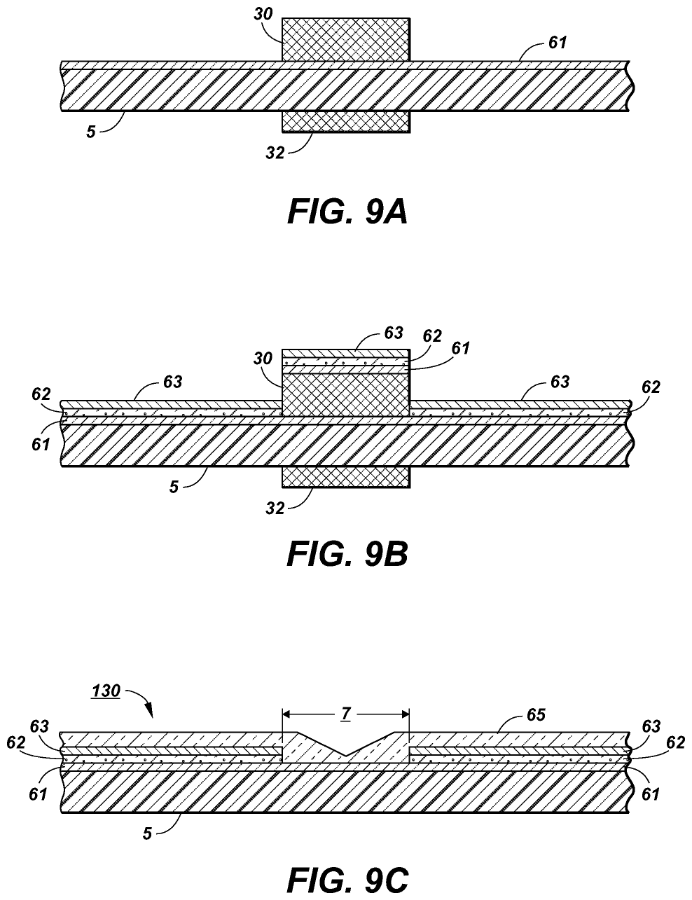

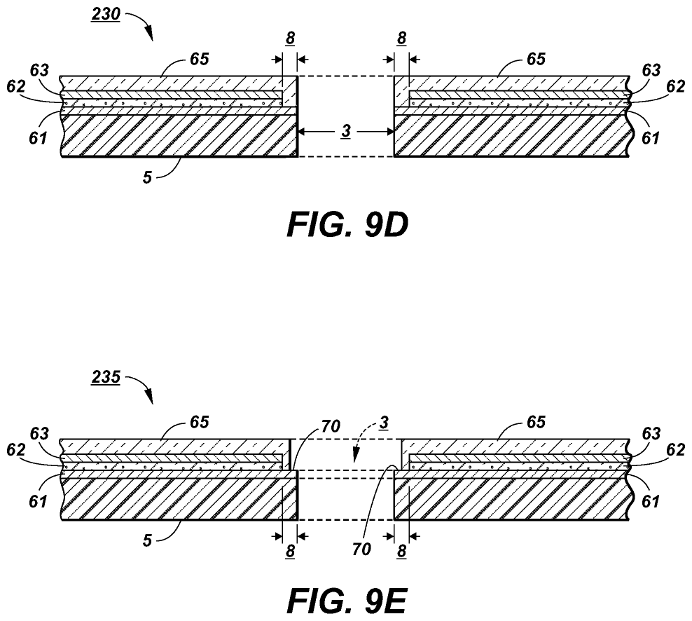

For example, analogous to the embodiment shown in FIGS. 6A-6C, the magnetic mask 30 can be located over a non-patterned and uniform layer of the first electrode (see FIG. 9A). In this example, the first electrode 61 extends to the outside edge of the substrate 5. The magnetic mask 30 is located on the upper surface of the first electrode 61 and held in place by magnetic mask holder 32. As shown in FIG. 9B, organic layer(s) 62 and second electrode 63 are deposited over the surface of the first electrode and magnetic mask 30, but not over the outside edge of the first electrode 61/substrate 5. Removal of the magnetic mask 30 (and the overlying layers), followed by formation of the encapsulation 65 results in OLED panel 130 with a non-light emitting area 7 as shown in FIG. 9C. Note that the first electrode 61 extends into and completely through non-light emitting area 7. Formation of a pass-through hole 3 that is smaller than non-light-emitting area 7 forms OLED panel 230 which has a fully encapsulated and non-light-emitting area 8 surrounding the pass-through hole 3 as shown in FIG. 9D. In this example, the first electrode 61 extends through the non-light-emitting border 8 and forms (along with the substrate 5) part of the side wall of the pass-through hole 3 and is covered with encapsulation 65. As shown in FIG. 9E, partial removal of the encapsulation 65 along the side wall exposes a portion of the first electrode 61 (forming contact pad 70) in OLED panel 235, which can be connected to an external power source to form an internal power source.

Although the embodiment shown in FIGS. 9A-9E illustrates the use of a magnetic shadow mask, other methods, such as the ablation or shadow masking methods discussed above, can also be used to generate similar lighting panels with electrode contact pads positioned along the pass-through hole. By appropriate design, the internal contact pads may be for contacting the first electrode, the second electrode or both. When the OLED panel has contact pads for both electrodes along the pass-through hole, the pads should not be in electrical contact with each other and should be spaced apart.

The OLED panel with the pass-through hole has an OLED light-emitting unit on an OLED substrate. The OLED light emitting unit refers to a complete light-emitting unit located on an OLED substrate. A complete light-emitting unit will have at least a first electrode, electroluminescent layer(s), and a second electrode, all fully covered by encapsulation to prevent contact with air and water.

The OLED substrate can be rigid and made of glass, metal or rigid plastic. Alternatively, the OLED substrate is flexible and can be made of flexible glass, metal or polymeric materials. Metal, glass or flexible glass are most desired. Generally speaking, it will be flat with a uniform thickness. In some cases, it may be necessary to provide features in the substrate in order to increase flexibility. If the substrate is flexible glass, the glass edge may be thermally treated to remove any surface defects. Defects such as nicks or defects in the glass edge can be the origin or starting points for glass breakage under stress. Heat treatment can prevent this by removing any defects and so, increase effective bendability without breaking. For bottom emitting OLEDs, the substrate should be transparent. For top emitting OLEDs, the substrate may be opaque or transparent (allowing for two-sided emission) as desired. The top surface of the substrate is that facing the OLED unit. Since the substrate will be part of the overall encapsulation for the OLED, it should be sufficiently impervious to air and water so that the OLED will have desired lifetime. The OLED substrate may have various types of subbing layers which may be patterned or unpatterned and can be either on the top or bottom surfaces.

In the OLED unit, there is a first electrode that covers the top surface of the substrate and desirably completely covers the top surface of the substrate. The first electrode can be an anode or a cathode and can be transparent, opaque or semi-transparent. Desirably, the first electrode is a transparent anode and the OLED device is a bottom emitter. The transparent first electrode should transmit as much light as possible, preferably having a transmittance of at least 70% or more desirably at least 80%. However, in some applications (i.e. microcavity devices), the transparent first electrode may only be semi-transparent and have partial reflectivity. While the first transparent electrode may be made of any conductive materials, metal oxides such as ITO or AZO or thin layers of metals such as Ag are preferable. In some cases, there may be an auxiliary electrode to help distribute charge more uniformly across the full plane of the transparent electrode.

Organic layers for light-emission will be deposited and will be in contact with the first electrode. At least one organic layer will be electroluminescent. There may be more than one layer and some layers may not be light-emissive. Formulations and layers appropriate for OLED type light emission are well known and can be used as desired. The organic layers may be small molecule or polymeric. The organic layers may be deposited by any known method including vapor deposition, solution coating, ink-jet techniques, spraying and the like. The organic layers may be patterned. Inorganic electroluminescent materials such as quantum dots could also be used for light emission. Because such formulations also include organic materials, the use of inorganic electroluminescent materials can be considered as an OLED for the purpose of the invention. The organic layers can also include various other layers well-known in the art, including but not limited to hole-injecting, hole-transporting, electron-injecting, and electron-transporting layers. There may be multiple stacked or tandem light-emitting units, each separated by an intermediate connector or charge generation layer, as known in the art.

Over the organic layers, there is a second electrode. It may be an anode or a cathode; preferably a cathode. The second electrode may be transparent or opaque, preferably opaque. If transparent, it is desirably composed of conductive transparent metal oxides such as ITO or thin layers of metals such as Ag. If opaque, it is desirably composed of a thicker layer of metal or metal alloy such as Al, Ag, Mg/Al, Mg/Ag and the like. The second electrode may be deposited by any known technique.

Over the second electrode, there may optionally be a protective organic layer, protective inorganic layer, or a combination of both. This is to prevent damage to the second electrode and underlying organic layers during encapsulation.

The OLED light-emitting unit should be fully encapsulated. By “fully encapsulated”, it is meant that all surfaces, including the cut edges (side walls) of the pass-through hole, are protected by materials that are impervious to water and oxygen. In particular, there should always be encapsulation material between the side edge of the OLED organic layer(s) and the cut edge or side wall of the pass-through hole. Desirably, the encapsulation material has a water vapor transmission rate (WVTR) of 10⁻⁶ g/m²//day or less. Desirably, the encapsulation is also a barrier to oxygen and has an oxygen transmission rate of 10⁻⁴ g/m²//day or less. The encapsulation is provided on one surface by the substrate. The sides and top as well as along the side walls of the pass-through hole of the OLED unit can be encapsulated by a rigid or flexible impervious cover that is affixed to the substrate to seal the OLED unit. Most desirably, the encapsulation of the sides and top of the OLED unit as well as along the side walls of the pass-through hole is provided by thin-film encapsulation. One kind of thin-film encapsulation typically includes multiple (for example, 4 or more) alternating layers of inorganic and organic materials. Alternatively, another kind of thin film encapsulation can be a flexible polymeric film such as metallized PET. It may or may not contain getter or desiccant particles. Such polymeric films are often pre-formed and attached to the substrate using moisture-proof adhesives. There are electrically conductive extensions of the first and second electrodes that will extend through the encapsulation and form contact pads for external electrical connection. Since the substrate is part of the OLED encapsulation, it may be necessary to add additional thin-film encapsulation such as barrier layers on either side of the substrate to provide additional protection. The additional barrier layer(s) may be the same as that applied over the OLED unit or made of different materials.

The OLED panel can be suitable for general lighting applications. It may be suitably modified for use in specific applications. For example, it may be fitted with a lens to concentrate the emitted light in order to act as highlighting or it may be fitted with filters to adjust the color temperature of the emitted light. It may be directly used as part of a specific luminaire design or may be used as the light source in a lighting module which can be used interchangeably between different luminaire designs.

The OLED lighting panel has at least one light-emissive face or surface. The opposite face or surface of the OLED panel can be non-emitting so that the OLED panel has single sided emission. The opposite face or surface can also be light-emitting so that the OLED panel has dual sided emission. The light-emitting surface(s) can have emissive areas and non-emission areas, not including the pass-through hole. Desirably, the non-emissive areas (not including the non-light emitting area around the pass-through hole) will be an outside border surrounding a single emissive area and will have a total non-emissive area less than the emissive area. It is most desirable that the OLED panel has single sided emission where the outside non-emitting areas around the emitting area are as small as possible.

The OLED panel may have an optional light management unit which serves a number of purposes and may be composed of multiple layers. It may be rigid or flexible. Its primary purpose is to increase the amount of light scatter of the light being transmitted through the OLED substrate, thus improving light distribution from the device and improving overall efficiency. Generally, the flexible light management unit will have a light scattering medium located either on the surface or within a flexible polymeric or glass substrate or the flexible substrate will contain physical structures (for examples, bumps or projections of various shapes) that cause light scattering. In some cases, the flexible light management unit may be part of the same substrate as the OLED unit. In other cases, it may be a separate unit that is applied to the light-emitting surface of the OLED unit/substrate using an optically clear adhesive. In addition to its light management function, it will also help to protect the surface of the device from damage. There may be a pass-through hole in the light management unit that corresponds to the pass-through hole in the OLED panel.

OLED panels can be used as a light source in a luminaire or lamp. Luminaires are used in many ways; for example, overhead lighting such as chandeliers, wall lighting such as sconces or table lighting such as desk lamps. In order to minimize production costs, it is often desirable to incorporate the OLED lighting panel in a modular design that can be used in many different styles of luminaires. An OLED lighting module would be a set of standardized parts or independent units that can be used to construct a more complex structure using an OLED lighting panel as the light source.

Generally speaking, an OLED module would have at least three parts: a bottom housing or support, an OLED lighting panel in the middle and a top housing or bezel with an opening for light emission. The bottom housing may also have an opening for light emission as well if using an OLED panel that emits light from two sides or if two OLED light panels are used back-to-back. In some instances, the top and bottom housing are formed as one integral piece, in which case the OLED panel is placed into the module through a side opening. To maintain a slick and neat appearance, the external electrical connections are usually hidden within the module and external electrical connections are through a standardized non-permanent connection point such as an electrical jack or plug. This is consistent with a modular design. The lighting module should also have some allowance for mechanical support and/or attachment to the body of the luminaire. The module may be rigid or flexible and may be made of any suitable material such as plastic or metal.

If the OLED panel with a pass-through hole is incorporated as part of a module, the module may have corresponding pass-through hole(s) as well if desired. If the OLED panel has a solid element that extends through the pass-through hole of the panel, then the OLED module will require an opening for the solid element to extend through as well. For luminaires using OLED modules with OLED panels with a solid element that extends through a pass-through hole, the solid element becomes part of the overall design and appearance of the luminaire. In such a case, it is preferred that the solid element provides mechanical support for the OLED module.

There are many ways to form a pass-through hole in a fully encapsulated OLED panel with an arranged non-emitting area. Some suitable methods of creating an opening in an OLED include drilling, grinding, scoring, die-punching, sawing, laser cutting, ultrasonic cutting, waterjet cutting or plasma cutting. However, any such methods will, at a minimum, create cut edges where the internal layers could be exposed to the atmosphere if the cuts are made through the internal layers. Moreover, the internal organic and electrode layers of the OLED are thin and not physically robust. They may shear or deform at and near the edges of the holes during hole formation. This is of particular concern for the electrode layers which may short circuit if they come into contact with each other during hole formation. This will cause the OLED to become nonfunctional. In additional, some of the organic materials used in OLEDs can be temperature sensitive or volatile at high temperatures. Of the above methods, drilling, ultrasonic cutting and laser cutting are preferred. Thus, the OLEDs of the invention have the sensitive internal layers arranged to lie outside a non-light emitting area where the pass-through hole will be formed.

In particular, the pass-through hole in the central non-light emitting area OLED panel may be made using laser cutting/ablation, water-jet cutting, plasma cutting, CNC, EDM, and the like, though in some cases techniques other than laser ablation and the like may be too destructive for very thin plastic substrates. Thus, in some embodiments, laser cutting processes such as laser ablation may be preferred. An example of suitable laser cutting process would use an IRR femtosecond laser.

Relative to other methods, laser cutting or ablation is a non-contact technique which causes little or no damage to the organic devices. Laser ablation may be especially effective in removing metals, since metals strongly absorb laser energy. The difference in energy absorption behavior between organics, oxides and metal materials can be exploited to optimize the process condition. CO₂ or Nd-YAG pulsed lasers can be used to remove cathode material. Further, laser power and wavelength can be changed to control etch depth and provide material selectivity.

It is also possible that the pass-through hole may be formed in a multistep process. For example, etching or laser ablation may be used to remove some or all of the layers overlying the substrate in a first step, and then the pass-through hole is completed by cutting the substrate and any remaining layers in a second step. Since wet solutions typically cannot be used on completed OLEDs, dry etching techniques may be applied. However, dry etch involves highly reactive chemicals and high energy plasmas, which may damage some OLED devices.

Laser cutting techniques also may be used to cut through a substrate. Under laser irradiation, many common substrate materials ablate, melt, burn, or vaporize, resulting in a clean cut. Other cutting processes also may be used to cut through a substrate. For example, a mechanical blade or knife, such as the Graphtec FC4500 flatbed cutter, may be used to cut the substrate. Such techniques may have an advantage in causing little or no debris.

Advantages of laser cutting over mechanical cutting include easier work-holding and reduced contamination of the workpiece, since there is no cutting edge which can become contaminated by the material or contaminate the material. The precision available with laser cutting techniques may be higher and/or more consistent, since the laser beam does not wear during the process. There is also a reduced chance of warping the material that is being cut, as laser systems have a small heat-affected zone. Some materials are also very difficult or impossible to cut by more traditional means.

Because water and oxygen are deleterious to the materials used in OLEDs, it is preferred to form the pass-through hole under conditions that are as free from water and oxygen as possible. This may involve forming the pass-through hole under an inert atmosphere in a sealed environment or at least under a blanket of inert and/or dry gases.

In order to provide sufficient protection against water and oxygen penetration into the cut edges of the pass-through hole, it is desirable that the non-light emitting area surrounding the cut edges of the pass-through hole is at least 3 mm thick. That is, the lateral distance between the cut-edge of the pass-through hole and the side edge of the moisture sensitive light-emitting organic layer(s) is at least 3 mm. The space between the edge of the organic layer(s) and the cut-edge is at least partially filled with the encapsulation; desirably, completely filled with encapsulation material. There still may be an additional gap, which may be filled with getter particles, between the encapsulation and the organic layer(s).

In the above description, reference is made to the accompanying drawings that form a part hereof, and in which are shown by way of illustration specific embodiments which may be practiced. These embodiments are described in detail to enable those skilled in the art to practice the invention, and it is to be understood that other embodiments may be utilized and that structural, logical and electrical changes may be made without departing from the scope of the present invention. The description of any example embodiments is, therefore, not to be taken in a limiting sense. Although the present invention has been described for the purpose of illustration, it is understood that such detail is solely for that purpose and variations can be made by those skilled in the art without departing from the spirit and scope of the invention.

### Parts List

2 light emitting area
3 pass-through hole
4 non-light emitting area that surrounds the light-emitting area 2
5 substrate of OLED
6 complete OLED unit
7 non-light emitting area surrounded by light-emitting area 2
8 non-light emitting border around pass-through hole 3
9 cut edges of pass-through hole
10 insulating layer
12 thermal evaporation source
14 vapor plume of material for coating
16 shadow mask connectors
18 shadow mask
20 deposition substrate
30 magnetic mask
32 magnetic mask holder
61 first electrode
62 organic layer(s) for light emission
63 second electrode
64 OLED stack
65 encapsulation layer
67 protective layer
69 optical clear polymer film
70 contact pad
100 OLED
130 OLED
200 OLED
210 OLED
220 OLED
230 OLED
235 OLED

1-20. (canceled)

21. A fully encapsulated OLED panel comprising:
a pass-through hole with cut edges;
a first area for light emission which entirely surrounds a non-light emitting second area that forms a border that entirely surrounds the pass-through hole;
a substrate that extends throughout the first area and second areas to the cut edges of the pass-through hole;
an insulating layer patterned over the substrate to fill the second area but is not present in the first area;
a first electrode over the substrate located at least in the first area;
at least one organic layer for light emission located over the first electrode in the first area but is not present in the second area so that the insulating layer in the second area provides encapsulation for the side edges of the at least one organic layer in the first area;
a second electrode located over the at least one organic layer in at least in the first area;
an encapsulation layer located over the second electrode in first area, over the insulating layer in the second area and extends at least partially along the cut-edges of the pass-through hole.

22. The OLED panel of claim 21 where the insulating layer comprises glass frit or aluminum oxide.

23. The OLED panel of claim 21 where the first electrode is located in the first area but not in the second area.

24. The OLED panel of claim 21 where the second electrode is located in the first area but not in the second area.

25. The OLED panel of claim 21 where the minimum width of the non-emitting second area running from the cut edges of the pass-through hole to the edge of the first area is at least 3 mm in all directions.

26. The OLED panel of claim 21 is an OLED lighting panel for illumination.

27. The OLED panel of claim 26 where the OLED lighting panel has an emission surface of 10,000 mm² or less and the pass-through hole has an area of at least 1.7 mm².

28. The OLED panel of claim 26 where the OLED lighting panel has an emission area of greater than 10,000 mm² and the pass-through hole has an area of at least 0.017% of the total emission surface.

29. (canceled)

30. A method for making the OLED panel of claim 21 comprising:
forming a first electrode on at least a first area of a substrate that has first and second areas, wherein the first area completely surrounds the second area; and wherein the second area and not the first area comprises an insulating layer;
forming at least one organic layer for light emission over the first electrode in the first area and the second area;
forming a second electrode over the at least one organic layer;
removing the at least one organic layer and second electrode in the second area by laser ablation;
forming encapsulation over the second electrode in the first area and over the insulating layer in the second area;
forming a pass-through hole with cut-edges through the second area, where the area of the pass-through hole is smaller than the second area so that the second area forms a non-emitting border that entirely surrounds the pass-through hole, and where the insulating layer provides at least part of the encapsulation along the cut-edges of the pass-through hole.

31. The method of claim 30 where the insulating layer comprises glass frit or alumina oxide.

32. (canceled)

33. The OLED panel of claim 21 where the height of the insulating layer is the same as or greater than an OLED stack which comprises the first electrode, the at least one organic layer and second electrode.
